(19) United States
(12) Patent Application Publication
(10) Pub. No.: US 2025/0267819 A1
(43) Pub. Date: Aug. 21, 2025

(54) LIQUID COOLED POWER AMPLIFIER WITH INTERNAL FLUID CHANNELIZATION

(71) Applicant: BAE Systems Information and Electronic Systems Integration Inc., Nashua, NH (US)

(72) Inventors: Edward Thoman, Merrimack, NH (US); Harallamby Papa, Litchfield, NH (US)

(73) Assignee: BAE Systems Information and Electronic Systems Integration Inc., Nashua, NH (US)

(21) Appl. No.: 18/582,225

(22) Filed: Feb. 20, 2024

(51) Int. Cl. H05K 7/20; H01L 23/44

(52) U.S. Cl. CPC H05K 7/20236; H01L 23/44; H05K 7/20272; H05K 7/20281; H05K 7/20409

(57) ABSTRACT

An electronic systems package hermetically sealed or equivalent with an electronics coolant liquid immersing the electronic components therein to absorb and dissipate heat away from these electronic components. Also provided is a housing including custom channelization to induce convective eddy currents in an electronics coolant liquid to further direct heat away from sensitive electronic components therein.

### STATEMENT OF GOVERNMENT INTEREST

This invention was made with government support under Prime Contract Number N00019-19-C-1025 awarded by the Navy. The government has certain rights in the invention.

### TECHNICAL FIELD

The present disclosure relates generally to electronic module packaging.

### BACKGROUND

Electronic systems technology is a rapidly evolving field and includes functional electronic systems that are commonly contained in a single package. These packages typically include integrated circuits and other electronic components therein which may be then further integrated into larger systems. Many of these components are high powered, high performance devices that may cause an increase in heat production by the components of the electronic system package. As these technologies improve, performance increases require additional power input, which, coupled with a push towards reduced size of many electronic packages, can created thermal loads that tend to exceed the capability of traditional package thermal dissipation techniques and/or technologies.

In particular, the higher performance requirement of electronic components in modern electronic systems can drive localized thermal loads at the individual integrated circuits, which may create an excess buildup of localized heat that surpasses the temperature rating of the devices. This in turn can cause degradation of the performance of the integrated circuits and/or premature failure even where the circuits are operated at temperatures considered within the normal operating range, their lifespan is reduced based on the excess temperature.

According to one example, current power amplifiers may operate between 140 and 150 watts with temperatures ranging between 300-400 degrees Celsius, or more. Some of these power amplifier systems have very short lifespan measured in a matter of minutes or hours and decreased temperature can increase the useable life of the component unit substantially. According to one aspect, every 50-degree Celsius decrease in temperature may increase the life of such a component by an order of magnitude. For example, a power amplifier with a standard 100-hour life may be extended to 1000 hours by decreasing the operating temperature by 50 degrees Celsius or more.

Current heat dissipation solutions are typically applied under the die and are limited in their ability to effectively dissipate heat away from the die and other electronic components within the electronics package. Common heat dissipation and management solutions tend to include strategies such as spreading the heat out amongst several surfaces, dissipating the heat using multiple heat sinks, and the like. However, these solutions are limited and are typically employed underneath the die and into the housing of the electronic components. The immersion of the die into fluid removes heat from all surfaces of the die, therefore creating multiple, parallel cooling paths.

### SUMMARY

The present disclosure addresses these and other aspects by providing, in one aspect, an electronic systems package hermetically sealed with an electronics coolant liquid immersing the electronic components therein to absorb and dissipate heat away from these electronic components. In another aspect, the present disclosure addresses these and other issues by providing a housing including custom channelization to induce convective current in an electronics coolant liquid to further direct heat away from sensitive electronic components therein.

In one example, the present disclosure relates to a compact, hermetically sealed electronics package utilizing an electronics coolant liquid to cool interior electronic components. In another example, the present disclosure relates to a compact, hermetically sealed electronics package utilizing an electronics coolant liquid to cool interior electronic components via induced conductive eddy currents within the package to circulate the electronics coolant liquid.

In one aspect, an exemplary embodiment of the present disclosure may provide an electronics module package comprising: a housing defining an internal cavity therein; a cover hermetically sealed to the housing; at least one port defined through the cover and in fluid communication with the internal cavity of the housing; at least one die within the internal cavity in the housing; and at least one electronic component within the housing; wherein the internal cavity is filled with an electronics coolant liquid and the at least one die and at least one electronic component are immersed in the electronics coolant liquid. This exemplary embodiment or another exemplary embodiment may further provide at least one bellows defined through the cover and in fluid communication with the internal cavity of the housing. This exemplary embodiment or another exemplary embodiment may further provide a heat sink; and a plurality of grooves formed in an exterior surface of the heat sink. This exemplary embodiment or another exemplary embodiment may further provide wherein the heat sink further comprises: a copper heat sink defining a back of the housing; wherein the heat sink contacts the electronics coolant liquid on a side opposite the grooves formed in the exterior surface thereof. This exemplary embodiment or another exemplary embodiment may further provide wherein the at least one die further comprises: at least one gallium nitride die.

In another aspect, an exemplary embodiment of the present disclosure may provide an electronics module package comprising: a housing defining an internal cavity therein; a cover hermetically sealed to the housing; a base layer within the internal cavity of the housing; a first fluid aperture defined through the base layer of the housing at a first end thereof; a second fluid aperture defined through the base layer of the housing at a second end thereof; a channel extending under the base layer of the housing and connecting the first and second fluid apertures; at least one die within the internal cavity in the housing; and at least one electronic component within the housing; wherein the internal cavity is filled with an electronics coolant liquid and the at least one die and at least one electronic component are immersed in the electronics coolant liquid. This exemplary embodiment or another exemplary embodiment may further provide wherein the first fluid aperture further comprises: a plurality of first fluid apertures. This exemplary embodiment or another exemplary embodiment may further provide wherein the second fluid aperture further comprises: a plurality of second fluid apertures. This exemplary embodiment or another exemplary embodiment may further provide wherein the channel further comprises: a plurality of channels wherein each channel of the plurality of channels connects a single aperture from the plurality of first apertures to a single aperture from the plurality of second apertures. This exemplary embodiment or another exemplary embodiment may further provide a heat sink in fluid communication with the electronics coolant liquid via the channel extending under the base layer and the first and second fluid apertures; and a plurality of grooves formed in an exterior surface of the heat sink. This exemplary embodiment or another exemplary embodiment may further provide wherein the heat sink further comprises: a copper heat sink defining a back of the housing; wherein the heat sink contacts the electronics coolant liquid within the channel and is operable to draw heat out of the electronics coolant liquid and into an environment surrounding the electronic module package. This exemplary embodiment or another exemplary embodiment may further provide wherein the at least one die further comprises: at least one gallium nitride die. This exemplary embodiment or another exemplary embodiment may further provide wherein the at least one die is located at the second end of the internal cavity adjacent the second fluid aperture. This exemplary embodiment or another exemplary embodiment may further provide wherein the electronics coolant liquid surrounds the at least one die and is operable to draw heat away therefrom. This exemplary embodiment or another exemplary embodiment may further provide wherein the electronics coolant liquid is operable to reduce the temperature of the at least one die by at least twenty degrees Celsius.

In yet another aspect, an exemplary embodiment of the present disclosure may provide a method of thermal management of an electronics module package comprising: generating heat through the operation of at least one die within an internal cavity of a hermetically sealed electronics module package; drawing the heat generated by the at least one die into an electronics coolant liquid surrounding the at least one die; and dissipating the heat out of the electronics coolant liquid and into an environment surrounding the electronics module package through a heat sink in fluid communication with the electronics coolant liquid. This exemplary embodiment or another exemplary embodiment may further provide directing heated electronics coolant liquid away from the at least one die and into a channel extending under a base layer of the electronics module package. This exemplary embodiment or another exemplary embodiment may further provide drawing heat out of the electronics coolant liquid with a heat sink in fluid communication with the channel and electronics coolant liquid; and dissipating the heat away from the electronics coolant liquid and into an environment surrounding the electronics module package to cool the electronics coolant liquid. This exemplary embodiment or another exemplary embodiment may further provide directing the cooled electronics coolant liquid out of the channel and towards the at least one die. This exemplary embodiment or another exemplary embodiment may further provide continuously circulating the electronics coolant liquid within the internal cavity of the electronics module package to draw heat away from the die and into the surrounding environment through the heat sink.

### BRIEF DESCRIPTION OF THE SEVERAL VIEWS OF THE DRAWINGS

Sample embodiments of the present disclosure are set forth in the following description, are shown in the drawings and are particularly and distinctly pointed out and set forth in the appended claims.

FIG. 1 (FIG. 1) is an overhead isometric perspective view of an exemplary electronics module package according to one aspect of the present disclosure.

FIG. 2 (FIG. 2) is an overhead isometric perspective view of the interior of an exemplary electronics module package according to one aspect of the present disclosure.

FIG. 3 (FIG. 3) is an overhead top plan view of the interior of an exemplary electronics module package according to one aspect of the present disclosure.

FIG. 4 (FIG. 4) is a side elevation cross sectional view of the interior of an exemplary electronics module package taken in the direction of line 4-4 indicated in FIG. 3 according to one aspect of the present disclosure.

FIG. 5 (FIG. 5) is a first elevation cross sectional view of the interior of an exemplary electronics module package taken in the direction of line 5-5 indicated in FIG. 3 according to one aspect of the present disclosure.

FIG. 6 (FIG. 6) is a second elevation cross sectional view of the interior of an exemplary electronics module package taken in the direction of line 6-6 indicated in FIG. 3 according to one aspect of the present disclosure.

FIG. 7 (FIG. 7) is a plan view of the interior of an exemplary electronics module package including exemplary electronics components therein according to one aspect of the present disclosure.

FIG. 8 (FIG. 8) is a side elevation cross sectional operational view of the interior of an exemplary electronics module package taken in the direction of line 8-8 indicated in FIG. 7 according to one aspect of the present disclosure.

Similar numbers refer to similar parts throughout the drawings.

### DETAILED DESCRIPTION

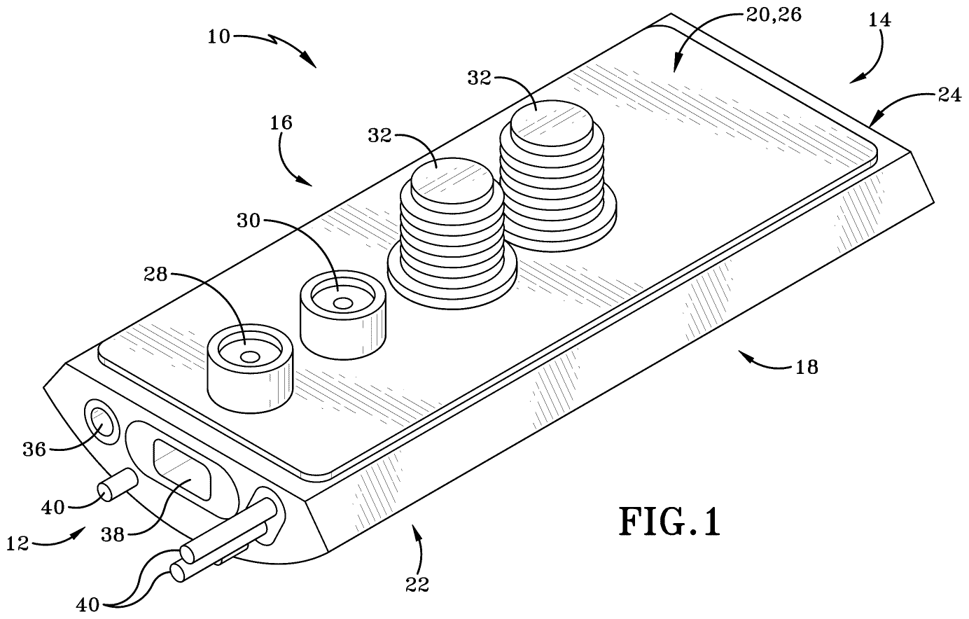

With reference to FIG. 1, an electronics module (EM) package, referred to herein as EM package is shown and generally indicated at reference 10. EM package 10 may generally have a first end 12 spaced apart from a second end 14 defining a longitudinal length of EM package 10 therebetween. Package 10 may further include a first side 16 spaced laterally apart from a second side 18 defining the width of the package 10 therebetween, and a top 20 spaced apart from a bottom 22 defining the vertical thickness of package 10 therebetween. These directions and dimensions will be understood to be relative to the orientation of package 10 and are for illustrative purposes and not limiting configuration of package 10 as discussed further herein.

At its most basic, EM package 10 may be an electronics module package that includes a housing 24 and a cover 26, which may further contain electronic components therein, as described further below. EM package 10 is generally contemplated for use with power amplifier electronics, including gallium nitride (GaN) and other similar electronic components that tend to generate significant heat; however, it will be understood that EM package 10 may be utilized for any suitable electronics or electronic components as desired, particularly those known to generate heat which result in a need for additionally cooling and/or heat management within an electronics module.

Accordingly, as shown and described herein and as exemplary electronics package, EM package 10 may generally include the housing 24 and the cover 26 which may enclose an internal cavity 44 (discussed below). Cover 26 may have one or more fill ports 28 and/or purge ports 30 connected thereto and defined therethrough. Similarly, cover 26 may include one or more bellows 32 connected thereto and defined therethrough.

Housing 24 may further include one or more mounting channels (not shown) which may allow for EM package 10 to be mounted or otherwise secured to another structure as dictated by the desired implementation. Mounting channels may be pass-through screw or rod channels for use in mounting EM package 10 in a suitable position as desired. According to another aspect, mounting channels may be any suitable mounting surface and or mounting structure as dictated by the desired implementation and use of EM package 10.

Housing 24 may have an exterior wall 58 (discussed further below) surrounding the outer perimeter and defining the interior cavity 44 therein. Exterior wall 58 may include suitable connectors and or ports to allow electronic communication between the interior electronic component 74 of EM package 10 and outside systems. As illustrated by way of common examples, housing 24 may include one or more jacks 36, one or more ports 38, and one or more wire pass-throughs 40. These jacks, ports, and/or pass-throughs 36, 38, and 40 may be any suitable connection components operable to connect the internal electronic components 74 of EM package 10 to other outside systems and may be sealed or otherwise configured to allow for hermetic sealing of EM package 10, as discussed further below.

Housing 24 may generally be formed of any suitable material; however, it is contemplated that housing 24 may be formed from heat conductive material, or may have heat conductive layers operable to dissipate heat from the interior of the housing 24 to the outside environment (e.g. to the air surrounding EM package 10). As discussed below, some advantages may be realized by utilizing mixed materials, such as copper and/or copper moly-layer or poly-layers within housing 24.

The bottom 22 of housing 24 may be the back side of a heat sink 62 (discussed below) and may further include a plurality of grooves (not shown) cut therein to aid in heat exchange and heat transfer with the external environment surrounding EM package 10 by increasing the surface area of the heat exchange surface of EM package 10, as discussed further herein with relation to the operation of EM package 10.

With continued reference to FIG. 1, fill port 28 may be a hermetically sealed port operable to allow an electronics coolant liquid (such as electronics coolant liquid 76) to be injected there through and into a central cavity 44 defined within the interior of EM package 10, as discussed below. In one aspect, fill port 28 may be a one-way port allowing specifically for fluid to pass from the exterior of EM package 10 and into the interior cavity 44 of EM package 10. According to another aspect, fill port 28 may be a combination of fill and purge port allowing fluid to pass both into and/or out of the internal cavity 44 as desired.

Similarly, purge port 30 may be a hermetically sealed port operable to allow fluid to pass out of internal cavity 44 and into the exterior environment of EM package 10 as a one-way valve or may alternatively, as with fill port 28, may be a two-way port which may allow movement of fluid both in and/or out of internal cavity 44, as discussed further below.

Bellows 32 may be any suitable bellows type operable to allow for expansion and contraction of the electronics coolant liquid 76 contained within internal cavity 44 of EM package 10. Bellows 32 permit expansion and contraction of the electronics coolant liquid 76 while keeping air or ambient atmosphere out of the EM package 10. As the liquid 76 heats and cools these bellows 32 may be adjustable in size and/or configuration to allow for proper expansion and contraction of both the electronics coolant liquid 76 and bellows 32 as dictated by the desired implementation. According to the aspect shown in FIG. 1, bellows 32 may be accordion style and may be defined through cover 26. However, it will be understood that bellows 32 may be any suitable bellows type and have any suitable configuration and or placement within EM package 10, as dictated by the desired implementation thereof.

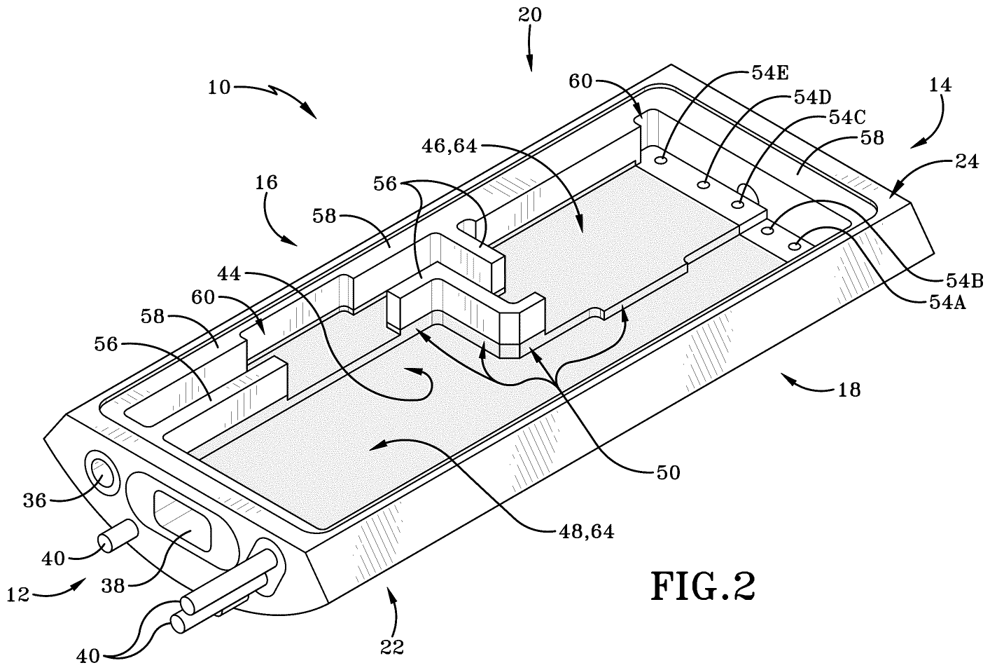

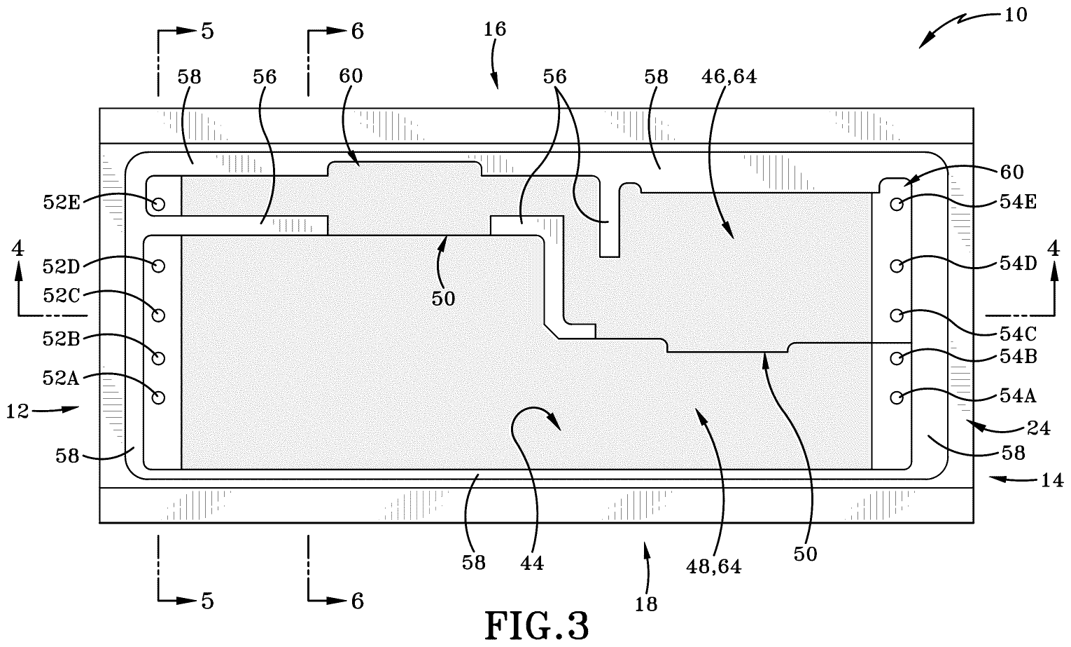

With reference to FIGS. 2 and 3, according to one exemplary embodiment, EM package 10 may include an internal cavity 44, which may generally be defined as the open space inside EM package 10 where electronic components and or dies may be located within housing 24. Cavity 44 may generally have the shape of the aforementioned exterior wall 58, which may surround and enclose cavity 44 therein. Displaced within cavity 44 may be a first platform or base 46 and a second platform or base 48, which may generally define a base 64 surface of EM package 10 on which electronic components may be mounted. First and second platforms 46 and 48 may generally be separated by a step 50, which may further allow for placement of various electronic components at different levels within cavity 44.

It will be understood that the package illustrated in the Figures is considered exemplary and EM package 10 and the placement and arrangement of components within cavity 44 may vary depending on the specific implementation and use of EM package 10. Therefore, it will be understood that some or all of the features described herein may be modified, moved, arranged differently and/or omitted as necessary or as dictated by the desired implementation thereof.

With continued reference to this exemplary embodiment a series of first fluid apertures 52 and second fluid apertures 54 may be defined in the base 64. As shown and best seen in FIG. 3, the fluid apertures 52 and 54 may be arranged towards the first and second ends 12 and 14 of EM package 10, respectively, to allow for dynamic fluid flow throughout EM package 10, as discussed further below. Apertures 52 and 54 are further labeled in the figures with letter designations A-E, which may correspond to the opposing aperture and to the associated channel 66 (discussed below). Put another way, first fluid aperture 52A may correspond to second fluid aperture 54A and channel 66A, while second fluid aperture 52B may correspond to second fluid aperture 54B and channel 66B, third aperture 52C may correspond to third fluid aperture 54C and channel 66C, and so forth.

EM package 10 may further include one or more interior walls or dividers 56, which may be strategically placed to separate various electronic components therein as dictated by the desired implementation thereof. Dividers 56 may generally be vertical and may be separate from or may be continuations of exterior wall 58. Dividers 56 may be placed in any suitable position as needed for the desired configuration of the electronics components 74 and dies 72 within EM package 10.

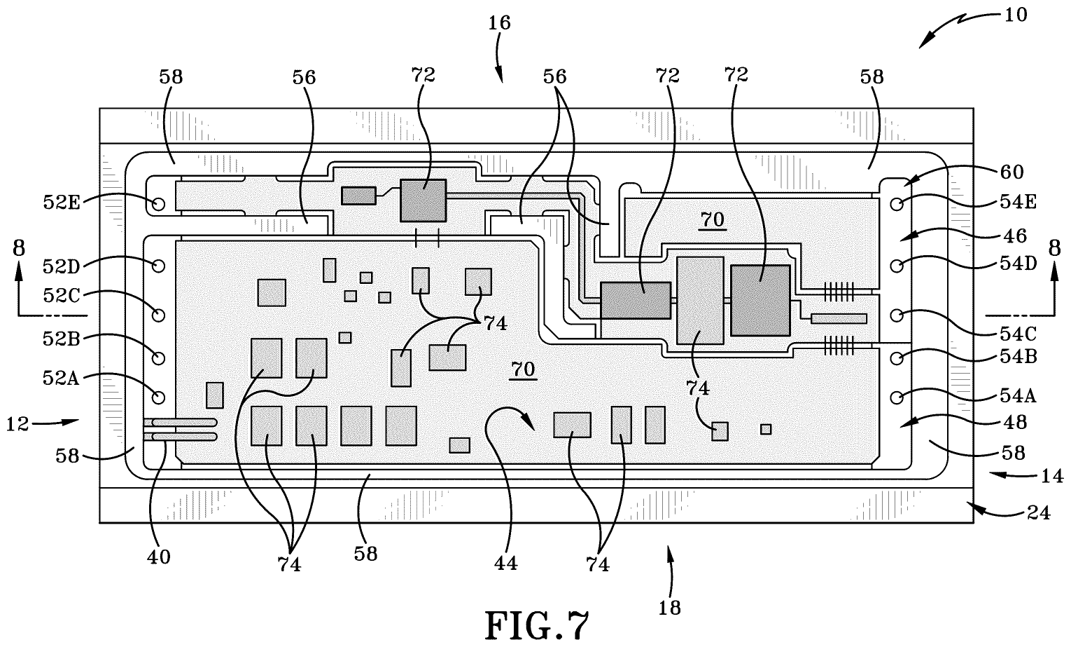

Exterior wall 58 may further include one or more cutouts 60 which may provide space for various electronic components 74 and or connections to reside and/or pass there through (best seen in FIG. 7), as desired. As with the dividers and other features discussed above, cutouts 60 may be provided in any suitable shape, position, or configuration to accommodate the specific electronic component layout as dictated by the desired implementation of EM package 10.

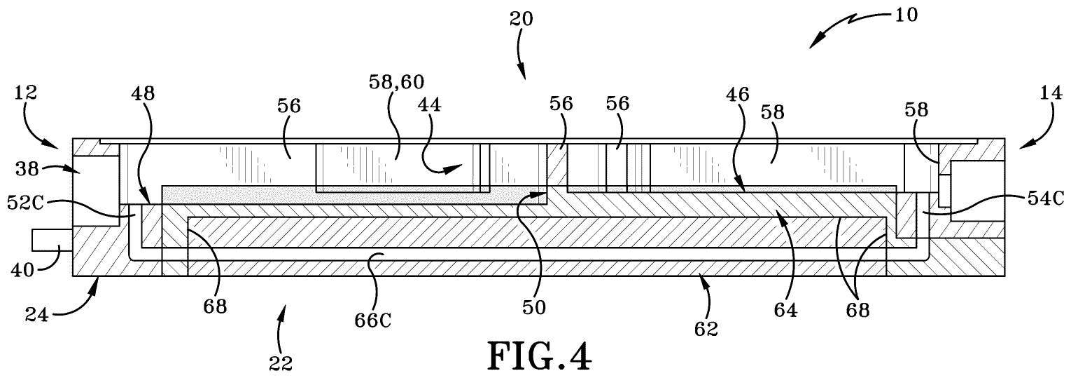

With reference to FIGS. 4-6, EM package 10 may include the aforementioned base 64 which may comprise, consist essentially of, or substantially consist of first and second platforms 46 and 48, but may further include a base housing layer 64 which may be a copper moly alloy (MoCu) or other similar heat conductive material (e.g., tungsten copper (WCu)), as dictated by the desired implementation. This may provide a suitable mounting surface for the platforms 46 and 48 as well as provide some heat transfer properties to the interior of the housing 24. However, other materials can be utilized to fabricated the base housing layer such as Copper-Invar-Copper (Cu/l/Cu), Copper-Molybdenum-Copper (Cu/Mo/Cu), Aluminum-Based Heat Sink Materials, Graphite Particles, or combination thereof. Base 64 may extend throughout the interior cavity 44 of EM package 10 and may generally define a bottom surface of cavity 44 upon which electronic component 74 and the like may be secured, as discussed further below.

EM package 10 may further include as heat sink layer 62 which may be exterior of base 64 and may further define or partially define the bottom 22 of housing 24. This heat sink layer or heat sink 62 may be copper, or other similar heat conductive material, that is suitable for rapid heat dissipation to cool various dies 72 and or electronic components 74 contained within cavity 44 of EM package 10. Heat sink 62 may be the outermost layer on the bottom 22 of EM package 10, and may be the layer that is exposed to the outside environment. Heat sink 62 may therefore further optionally include the grooves (i.e., defined by the heat sink fins) defined on the exterior surface thereof, which again may provide additional surface area for interaction with the external environment of EM package 10.

According to one example, grooves (and the surface of the heat sink fins) may interface with the air surrounding EM package 10 and may increase the surface area of the heat sink 62 to facilitate heat dissipation from heat sink 62 to the surrounding environment, as discussed further below.

The junction 68 between heat sink 62 and base 64 may be hermetically sealed utilizing braising or welding as necessary to hermetically seal cavity 44 of EM package 10 to prevent leakage of electronics coolant liquid 76 when contained therein, as discussed further below. Junction 68 may further define the interface between heat sink 62 and base 64 while further allowing some heat transfer there between so that heat may dissipate outwardly from base 64 through heat sink 62 and into the external environment.

With continued reference to FIGS. 4-6 EM package 10 may further include a series of fluid channels 66 which may extend between the first fluid apertures 52 and second fluid apertures 54. As illustrated therein and according this aspect, fluid channels 66 may connect first fluid apertures 52 to second fluid aperture 54 and are therefore labeled with corresponding letter identifiers A-E. For example, first fluid aperture 52A may connect to second fluid aperture 54A through fluid channel 66A, first fluid aperture 52B may connect to second fluid aperture 54B through fluid channel 66B, and so on.

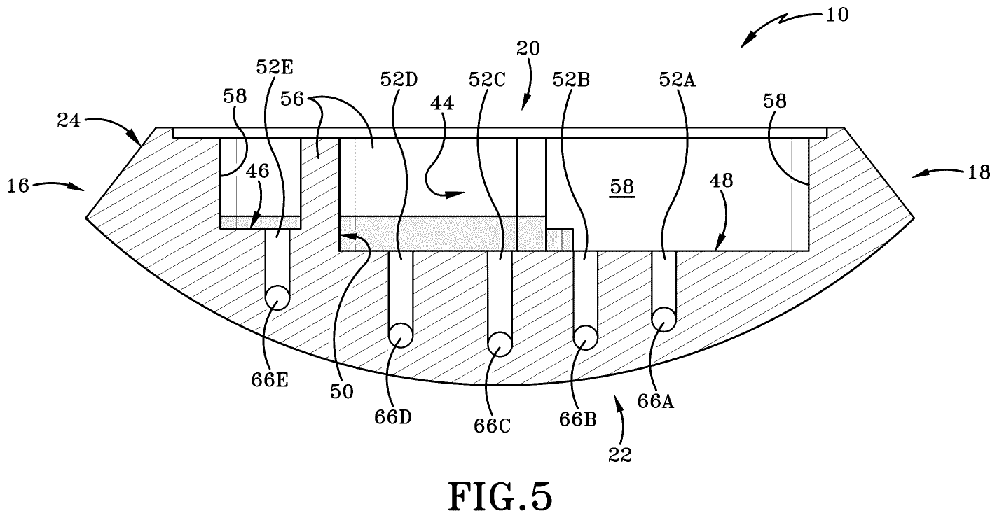

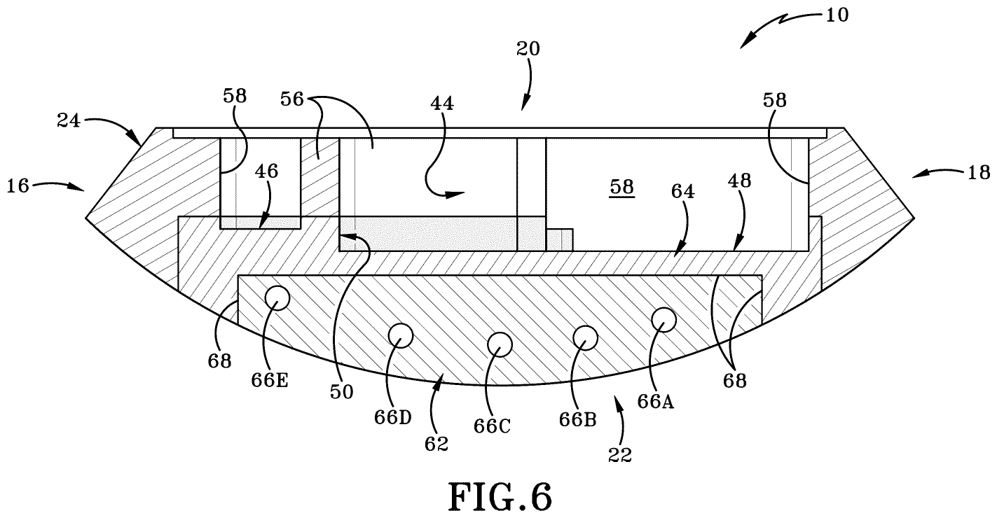

Each of these fluid channels 66 may be defined in the heat sink 62 layer of EM package 10 in connection with or otherwise abutting the base layer 64 at the junction 68 there between. As illustrated and best seen in FIGS. 5 and 6, the exception to the placement of the channels 66 may be for any channel near the sides 16 and 18 of EM package 10. These channels 66 that are located near the sides 16 and 18 of EM package 10 may then extend through the base layer 64 and not the heat sink 62 simply to provide for sufficient clearance for channel 66 to be formed or defined without disrupting or otherwise defeating the hermetic seal of EM package 10, as discussed further below. The channels 66 extend longitudinally between first and second fluid apertures 52 and 54 through heat sink 62 which allows better heat transfer from electronics coolant liquid 76 to the heat sink 62 and out of EM package 10, as discussed further below.

With reference to FIG. 7, an exemplary electronic component setup for EM package 10 is shown and will now be described. It will be understood that the arrangement, position, and components presented in FIG. 7 are again intended as an exemplary configuration and the placement, type, and configuration of these components may vary depending on the specific implementation of EM package 10.

Accordingly, EM package 10 may include one or more printed circuit boards 70 (PCB 70), which may carry one or more dies 72 and/or a plurality of electronic components 74 thereon. Electronic components 74 may be any suitable electronic elements including, but not limited to, processors, logics, gates, transistors, capacitors, transmitters, receivers, transceivers, antennas, or the like, or any suitable combinations thereof. Electronic components 74 may further include any additional or other common or necessary components for the operation of the electronics system contained within EM package 10 as desired.

Typically, it is common in electronic module packaging to isolate dies 72 from other electronic components 74 as much as possible, as dies 72 tend to generate significant heat when in operation. Accordingly, interior dividers 56 as well as the two level platform bases 46 and 48 may help isolate the dies from other electronic components 74 to assist in protecting those electronic components 74 from the heat generated by dies 72. As shown and described herein, the dies 72 may be positioned to either first or second end 12 or 14 of the cavity 44, adjacent to either the first or the second fluid apertures 52 or 54. One of the interior dividers may be generally S-shaped when viewed from above. Another interior divider may be generally L-shaped with one of the legs of the L-shaped divider being coextensive with exterior wall 58. The two dividers 56 may be spaced apart from one another, and between the two dividers 56, a channel is defined which permits coolant liquid to flow therethrough. The configuration of the dividers 56 assists with circulation or movement of coolant liquid without the need for a pump to circulate said coolant liquid.

As shown, the dies 72 are positioned towards the second end 14 of EM package 10, near the second fluid apertures 54. This placement will help induce the convective current within the package 10 to circulate the electronics coolant liquid 76 within the cavity 44, as discussed further below.

According to one aspect, dies 72 may be GaN dies suitable for use in power amplifiers. According to another aspect, dies 72 and the associated electronic components 74 may be any suitable electronic devices as dictated by the desired implementation and use of EM package 10.

As mentioned previously herein, it is contemplated that EM package 10 may be hermetically sealed to prevent fluid leakage as it is further contemplated that EM package 10 may be filled with an electronics coolant liquid 76 which may occupy all open spaces within cavity 44 and may further immerse and bathe the PCB 70, dies 72 and other electronic components 74 in an electronics coolant liquid. During filling of the coolant liquid 76, air will be evacuated out of the package 10 as it is dispersed by liquid 76. This electronics coolant liquid 76 may be any suitable coolant for use with electronic components, such as perfluorinated compounds (PFCs) or other suitable fluorocarbon based fluids. According to one example, the electronics coolant liquid 76 may be Fluorinert FC-40, which is a brand name of electronics coolant liquid owned and commercially available from 3M Company. According to another aspect, electronics coolant liquid 76 may be any suitable commercially available electronics coolant liquid. For example, other PFCs coolants may include Perfluoropolyethers (PFPEs). These are often used as mixtures under the trade name Galden™. For example, Galden™ HT-135 has a practical temperature range of −40° C. to +120° C. Additionally, there are Perfluoroalkanes, Perfluoroethers, and Tertiary Perfluoroamines. These are offered by 3M under as Fluorinert™ as FC-3283 that has a practical temperature range of −40° C. to +120° C. for use in chillers. As for other cooling liquids that are not PFCs but function in a similar manner, one example may include polyalphaolefin (PAO). Another example includes Hydrofluoroether (HFE) and Fluoroketone (FK) Fluids. These new segregated fluids are nonflammable and have lower Global Warming Potentials (GWPs) than PFCs. They compare favorably with the PAO fluids.

It is shown that dies, particularly GaN dies, utilized in power amplifier technology may operate at temperatures exceeding 300-400 degrees Celsius, which may reduce the useable life of the dies 72 and surrounding electronic components while further increasing both production and maintenance costs of similar and related systems as these dies 72 and other electronic components 74 tend to expire prematurely. Thus, the effect of the high operating temperature of the dies 72 is to reduce the effective lifespan while increasing manufacturing and maintenance costs for associated systems. Similarly, the reduction in lifespan may increase the effectiveness of related systems in that those systems may suffer from failures due to the overheating and premature failure of the dies 72 and/or electronic components 74. Similarly, critical systems utilizing such components often require redundant backups further increasing the cost and complexity of such systems.

It is well known then that reducing the heat buildup and managing the dissipation of the generated heat within an electronic module package, such as EM package 10, is critical for prolonging the life of the electronic components contained therein, including dies 72. It is a general rule that every 50 degrees Celsius of reduced operating temperature within an EM package, the useable lifespan of the electronic components contained therein may increase by an order of magnitude. Put another way, reducing the operating temperature from 400 degrees Celsius to 350 degrees Celsius could increase the lifespan of a related component from 100 hours to 1000 hours.

Accordingly, bathing and immersing all of the PCB 70, dies 72, and electronic components 74 within EM package 10 housing 24 in an electronics coolant liquid 76 has been shown to reduce the operating temperature of associated dies 72 by up to 20 degrees Celsius. Therefore, it is understood and will be easily realized that hermetically sealing EM package 10 to contain the electronics coolant liquid 76 therein can reduce the operating temperature of EM package 10 by up to 20 degrees Celsius as well, thus, improving the lifespan thereof substantially.

Additionally, channelizing the EM package 10 via first and second fluid apertures 52 and 54 and fluid channels 66, may further induce convective or heat driven eddy currents within the EM package 10 itself. In turn, the circulation of the electronics coolant liquid 72 throughout the package, may further reduce the operating temperature and increase the effective useable lifespan of EM package 10 and the electronics contained therein. Although the eddy currents effectuate coolant liquid to move or circulate, there are other manners in which liquid coolant 72 can circulate, which may occur in the absence of a pump. For example, thermosiphoning is a method of passive heat exchange which circulates a fluid without the necessity of a mechanical pump. In another example, it may be possible to utilize a volumetric momentum source. In another example, electroosmotic flow can cause the movement of liquid through a material under the influence of an electric field. In these examples, or other examples, there may optically be an electronic valve controlled by a timer.

Having thus described the features and benefits of EM package 10 the operation and use thereof will now be discussed.

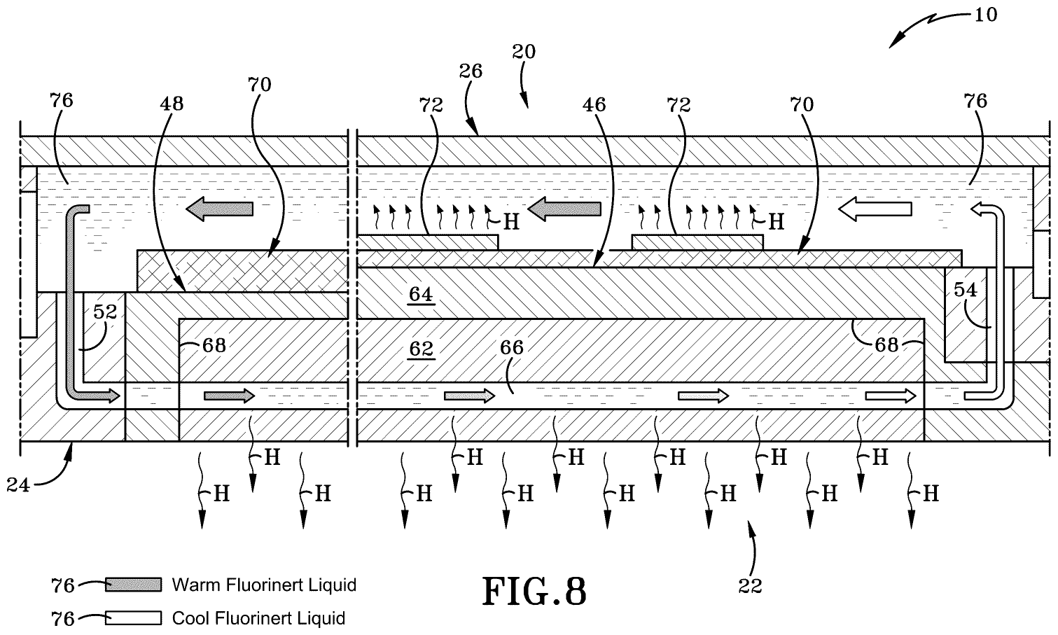

With reference to FIG. 8, EM package 10 may again be hermetically sealed and filled with an electronics coolant liquid 76. This may be accomplished by assembling all components within EM package 10, including PCB 70, dies 72, and/or electronic components 74, before affixing the cover 26 on housing 24 and hermetically sealing the internal cavity 44 from the external environment. At this point, electronics coolant liquid 76 may be introduced into the internal cavity 44 through any suitable process via the fill port 28, where the electronics coolant liquid 76 may full immerse all the elements within the internal cavity 44 of EM package 10 and may fill any gaps, or spaces within cavity 44 above the PCB 70, dies 72, electronic components 74, the first and second platforms 46 and 48, the base 64, and within the exterior walls 58 and cutouts 60. However it may possible to fill the cavity first with liquid 76 and then hermetically seal the EM package 10, thus eliminating the need for port 28. Once the EM package 10 is filled with electronics coolant liquid 76 it may be connected to related systems and or components via one or more of the jacks 36, ports 38, and/or wire pass-throughs 40, as dictated by the desired implementation. The components of EM package 10 may be powered and operated normally as an electronics module.

As mentioned herein, EM package 10 is contemplated and shown for use with power amplifier technology or other similar GaN electronic components. However, again, this is an exemplary use and EM package 10 may be suitable for use with any suitable electronics module and related components.

As the electronic components 74 and dies 72 within EM package 10 are operated it is common that these components will generate heat, which is shown by the arrows labeled H in FIG. 8. This heat is transferred from the dies 72 and to the electronics coolant liquid, which begin to increase in temperature and expand.

As the electronics coolant liquid 76 increases in heat the liquid volume will expand and may extend into bellows 32 to prevent an unsafe increase in pressure within EM package 10. Simultaneously, according to the laws of thermodynamics and fluid dynamics, the electronics coolant liquid 76 will begin to dissipate moving from areas of high heat and therefore high pressure to areas of lower heat and therefore lower pressure. This is shown by the shaded arrows in FIG. 8 with darker arrows representing higher temperature electronics coolant liquid 76 and lighter arrows representing lower temperature or cooler electronics coolant liquid 76.

As discussed above, the placement of dies 72 towards one end of EM package 10, as shown adjacent to second end 18, may cause the fluid to move away from dies towards first end 16 of EM package 10. As the warm electronics coolant liquid 76 moves away from dies 72 it will begin to move through first fluid apertures 52 and into channels 66. As the warm electronics coolant liquid 76 moves into these channels electronics coolant liquid 76 from the second end 14 of package 10 may be drawn or pulled towards the dies where it will similarly heat up. This may begin a convective current that continuously draws fluid from second end 14 of EM package 10 towards first end 12 within the cavity 44, while simultaneously drawing warm electronics coolant liquid 76 through channels 66 from first end 12 or EM package 10 towards second end 14 thereof.

As the warm electronics coolant liquid moves through the channels 66 heat is drawn out of the liquid through the contact between the electronics coolant liquid 76 and the heat sink 62, which may serve to dissipate heat out through heat sink 62 and into the surrounding environment, while simultaneously cooling the electronics coolant liquid 76 moving through channels 66. As the electronics coolant liquid 76 cools and is drawn through channels 66 it will move through second fluid apertures 54 and back into internal cavity 44, where it will again be drawn towards dies 76 and the cycle will repeat.

As mentioned above, just the inclusion of electronics coolant liquid 76 within cavity 44 and surrounding all sides of dies 72 and electronic components 74 is effective to reduce the operating temperature. The convective current of electronics coolant liquid 76 may serve to continuously replenish the supply of cool electronics coolant liquid 76 at the interface between the fluid 76 and dies 72 to more effectively drawn heat away from dies and towards first end of EM package 10, and ultimately through channels 66 to further enhance the heat dissipation capability of heat sink 62. Thus, reducing further the operating temperature of EM package 10 and increasing the effective lifespan of the dies 72 and electronic components 74 contained therein. This in turn may further reduce manufacturing and maintenance costs as well as system complexity as less heat may increase the useable lifespan of these components therefore, reducing the maintenance and replacement costs as well as reducing the need for redundant systems accordingly.

The device of the present disclosure may additionally include one or more sensors to sense or gather data pertaining to the surrounding environment or operation of the device. Some exemplary sensors capable of being electronically coupled with the device of the present disclosure (either directly connected to the device of the present disclosure or remotely connected thereto) may include but are not limited to: accelerometers sensing accelerations experienced during rotation, translation, velocity/speed, location traveled, elevation gained; gyroscopes sensing movements during angular orientation and/or rotation, and rotation; altimeters sensing barometric pressure, altitude change, terrain climbed, local pressure changes, submersion in liquid; impellers measuring the amount of fluid passing thereby; Global Positioning sensors sensing location, elevation, distance traveled, velocity/speed; audio sensors sensing local environmental sound levels, or voice detection; Photo/Light sensors sensing ambient light intensity, ambient, Day/night, UV exposure; TV/IR sensors sensing light wavelength; Temperature sensors sensing machine or motor temperature, ambient air temperature, and environmental temperature; and Moisture Sensors sensing surrounding moisture levels.

The device of the present disclosure may include wireless communication logic coupled to sensors on the device. The sensors gather data and provide the data to the wireless communication logic. Then, the wireless communication logic may transmit the data gathered from the sensors to a remote device. Thus, the wireless communication logic may be part of a broader communication system, in which one or several devices of the present disclosure may be networked together to report alerts and, more generally, to be accessed and controlled remotely. Depending on the types of transceivers installed in the device of the present disclosure, the system may use a variety of protocols (e.g., Wifi, ZigBee, MiWi, Bluetooth) for communication. In one example, each of the devices of the present disclosure may have its own IP address and may communicate directly with a router or gateway. This would typically be the case if the communication protocol is WiFi.

In another example, a point-to-point communication protocol like MiWi or ZigBee is used. One or more of the device of the present disclosure may serve as a repeater, or the devices of the present disclosure may be connected together in a mesh network to relay signals from one device to the next. However, the individual device in this scheme typically would not have IP addresses of their own. Instead, one or more of the devices of the present disclosure communicates with a repeater that does have an IP address, or another type of address, identifier, or credential needed to communicate with an outside network. The repeater communicates with the router or gateway.

In either communication scheme, the router or gateway communicates with a communication network, such as the Internet, although in some embodiments, the communication network may be a private network that uses transmission control protocol/internet protocol (TCP/IP) and other common Internet protocols but does not interface with the broader Internet, or does so only selectively through a firewall.

The system that receives and processes signals from the device of the present disclosure may differ from embodiment to embodiment. In one embodiment, alerts and signals from the device of the present disclosure are sent through an e-mail or simple message service (SMS; text message) gateway so that they can be sent as e-mails or SMS text messages to a remote device, such as a smartphone, laptop, or tablet computer, monitored by a responsible individual, group of individuals, or department, such as a maintenance department or team. Thus, if a particular device of the present disclosure creates an alert because of a data point gathered by one or more sensors, that alert can be sent, in e-mail or SMS form, directly to the individual responsible for fixing it. Of course, e-mail and SMS are only two examples of communication methods that may be used; in other embodiments, different forms of communication may be used.

As described herein, aspects of the present disclosure may include one or more electrical, pneumatic, hydraulic, or other similar secondary components and/or systems therein. The present disclosure is therefore contemplated and will be understood to include any necessary operational components thereof. For example, electrical components will be understood to include any suitable and necessary wiring, fuses, or the like for normal operation thereof. Similarly, any pneumatic systems provided may include any secondary or peripheral components such as air hoses, compressors, valves, meters, or the like. It will be further understood that any connections between various components not explicitly described herein may be made through any suitable means including mechanical fasteners, or more permanent attachment means, such as welding or the like. Alternatively, where feasible and/or desirable, various components of the present disclosure may be integrally formed as a single unit.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

All definitions, as defined and used herein, should be understood to control over dictionary definitions, definitions in documents incorporated by reference, and/or ordinary meanings of the defined terms.

The articles “a” and “an,” as used herein in the specification and in the claims, unless clearly indicated to the contrary, should be understood to mean “at least one.” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about” or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

1. An electronics module package comprising:
a housing defining an internal cavity therein;
a first fluid aperture defined through a portion of the housing at a first end thereof;
a second fluid aperture defined through another portion of the housing at a second end thereof;
a cover hermetically sealed to the housing defining a sealed internal cavity;
at least one die within the internal cavity in the housing; and
at least one electronic component within the housing; and
coolant liquid in the internal cavity, and wherein the at least one die and at least one electronic component are immersed in the electronics coolant liquid.

2. The electronics module package of claim 1 further comprising:
at least one port defined through the cover and in fluid communication with the internal cavity of the housing.

3. The electronics module package of claim 1 further comprising:
at least one bellow defined through the cover and in fluid communication with the internal cavity of the housing that is adapted to provide space for fluid expansion.

4. The electronics module package of claim 1, wherein the electronics coolant liquid is circulated without a pump.

5. The electronics module package of claim 1, further comprising:
a back of the housing, wherein the back of the housing is a heat sink that contacts the electronics coolant liquid on a side opposite the exterior surface thereof;
a plurality of channels that extend through the heat sink, wherein the coolant liquid circulates through the plurality of channels, wherein one channel from the plurality of channels extends between and is in fluid communication with the first fluid aperture and the second fluid aperture.

6. The electronics module package of claim 1, further comprising:
a first platform on a portion of a base of the housing;
a second platform on another portion of the base of the housing;
wherein the first platform and the second platform are separated by a step.

7. An electronics module package comprising:
a housing defining an internal cavity therein;
a cover hermetically sealed to the housing;
a base layer within the internal cavity of the housing;
a first fluid aperture defined through the base layer of the housing at a first end thereof;
a second fluid aperture defined through the base layer of the housing at a second end thereof;
a channel extending under the base layer of the housing and connecting the first and second fluid apertures;
at least one die within the internal cavity in the housing; and
at least one electronic component within the housing;
wherein the internal cavity is filled with an electronics coolant liquid and the at least one die and at least one electronic component are immersed in the electronics coolant liquid.

8. The electronics module package of claim 6 wherein the first fluid aperture further comprises:
a plurality of first fluid apertures; and
wherein the second fluid aperture further comprises:
a plurality of second fluid apertures.

9. The electronics module package of claim 8 wherein the channel further comprises:
a plurality of channels wherein each channel of the plurality of channels connects a single aperture from the plurality of first apertures to a single aperture from the plurality of second apertures.

10. The electronics module package of claim 7 further comprising:
an exterior surface of the heat sink;
a heat sink in fluid communication with the electronics coolant liquid via the channel extending under the base layer and the first and second fluid apertures, wherein the heat sink further comprises:
a copper heat sink defining a back of the housing;
wherein the heat sink contacts the electronics coolant liquid within the channel and is operable to draw heat out of the electronics coolant liquid and into an environment surrounding the electronic module package.

11. The electronics module package of claim 7
a first platform on a portion of a base of the housing;
a second platform on another portion of the base of the housing;
wherein the first platform and the second platform are separated by a step.

12. The electronics module package of claim 7 further comprising:
an S-shaped divider in the internal cavity.

13. The electronics module package of claim 12 further comprising;
a generally L-shaped divider wherein at least one of the legs of the L-shaped divider is coextensive with an exterior wall of the housing.

14. The electronics module package of claim 13 wherein the electronics coolant liquid surrounds circulates between the S-shaped divider and the L-shaped divider.

15. The electronics module package of claim 14 wherein the electronics coolant liquid is operable to reduce the temperature of the at least one die by at least twenty degrees Celsius.

16. A method of thermal management of an electronics module package comprising:
generating heat through the operation of at least one die within an internal cavity of a hermetically sealed electronics module package;
circulating, via convective eddy currents, an electronics coolant liquid within the internal cavity;
drawing the heat generated by the at least one die into the electronics coolant liquid surrounding the at least one die; and
dissipating the heat out of the electronics coolant liquid and into an environment surrounding the electronics module package through a heat sink in fluid communication with the electronics coolant liquid.

17. The method of claim 16 further comprising:
directing heated electronics coolant liquid away from the at least one die and into a channel extending under a base layer of the electronics module package.

18. The method of claim 17 further comprising:
drawing heat out of the electronics coolant liquid with a heat sink in fluid communication with the channel and electronics coolant liquid; and
dissipating the heat away from the electronics coolant liquid and into an environment surrounding the electronics module package to cool the electronics coolant liquid.

19. The method of claim 18 further comprising:
directing the cooled electronics coolant liquid out of the channel and towards the at least one die.

20. The method of claim 19 further comprising:
continuously circulating the electronics coolant liquid within the internal cavity of the electronics module package to draw heat away from the die and into the surrounding environment through the heat sink.
